(19) United States
(12) Patent Application Publication
(10) Pub. No.: US 2018/0006203 A1
(43) Pub. Date: Jan. 4, 2018

(54) ULTRAVIOLET EMITTING DEVICE

(71) Applicant: RayVio Corporation, Hayward, CA (US)

(72) Inventors: Saijin Liu, Hayward, CA (US); Xiaoning Wang, Hayward, CA (US); Yitao Liao, Redwood City, CA (US); Douglas A. Collins, Hayward, CA (US)

(21) Appl. No.: 15/200,991

(22) Filed: Jul. 1, 2016

(51) Int. Cl. H01L 33/60; H01L 33/62

(52) U.S. Cl. CPC H01L 33/60; H01L 33/62; H01L 2933/0066; H01L 2933/0058

(57) ABSTRACT

Embodiments of the invention include a light emitting diode (UVLED), the UVLED including a semiconductor structure with an active layer disposed between an n-type region and a p-type region. The active layer emits UV radiation. The UVLED is disposed on a mount. A reflective layer is disposed on a surface of the mount surrounding the UVLED.

### BACKGROUND

### Description of Related Art

The bandgap of III-nitride materials, including (Al, Ga, In)—N and their alloys, extends from the very narrow gap of InN (0.7 eV) to the very wide gap of AlN (6.2 eV), making III-nitride materials highly suitable for optoelectronic applications such as light emitting diodes (LEDs), laser diodes, optical modulators, and detectors over a wide spectral range extending from the near infrared to the deep ultraviolet. Visible light LEDs and lasers can be obtained using InGaN in the active layers, while ultraviolet LEDs (UVLEDs) and lasers require the larger bandgap of AlGaN.

UVLEDs with emission wavelengths in the range of 230-350 nm are expected to find a wide range of applications, most of which are based on the interaction between UV radiation and biological material. Typical applications include surface sterilization, air disinfection, water disinfection, medical devices and biochemistry, light sources for ultra-high density optical recording, white lighting, fluorescence analysis, sensing, and zero-emission automobiles.

The extraction efficiency from such UVLEDs is often undesirably low.

### BRIEF DESCRIPTION OF THE DRAWINGS

FIG. 1 is a cross sectional view of two packaged UV-emitting devices (UVLEDs).

FIG. 2 is a plan view of multiple pixels in a flip chip UVLED.

FIG. 3 is a cross sectional view of one pixel in the UVLED.

FIG. 4 illustrates absorption of radiative power in a large area UVLED.

FIG. 5 illustrates extraction of radiative power in a small area UVLED.

FIG. 6 is a top view of one of the devices illustrated in FIG. 1.

FIGS. 7, 8, 9, 10, and 11 illustrate one method of forming the device illustrated in FIG. 1.

FIG. 12 illustrates a packaged UVLED including a reflective layer in contact with a bonding pad and a mount.

FIGS. 13, 14, and 15 illustrate three structures on which the packaged devices may be mounted.

### DETAILED DESCRIPTION

Though the devices described herein are III-nitride devices, devices formed from other materials such as other III-V materials, II-VI materials, Si are within the scope of embodiments of the invention. The devices described herein may be configured to emit visible, UV A (peak wavelength between 340 and 400 nm), UV B (peak wavelength between 290 and 340 nm), or UV C (peak wavelength between 210 and 290 nm) radiation. The radiative power emitted by the UVLEDs described herein may be described as “light” for economy of language.

Embodiments of the invention are directed to structures and techniques for increasing the extraction efficiency from UVLEDs.

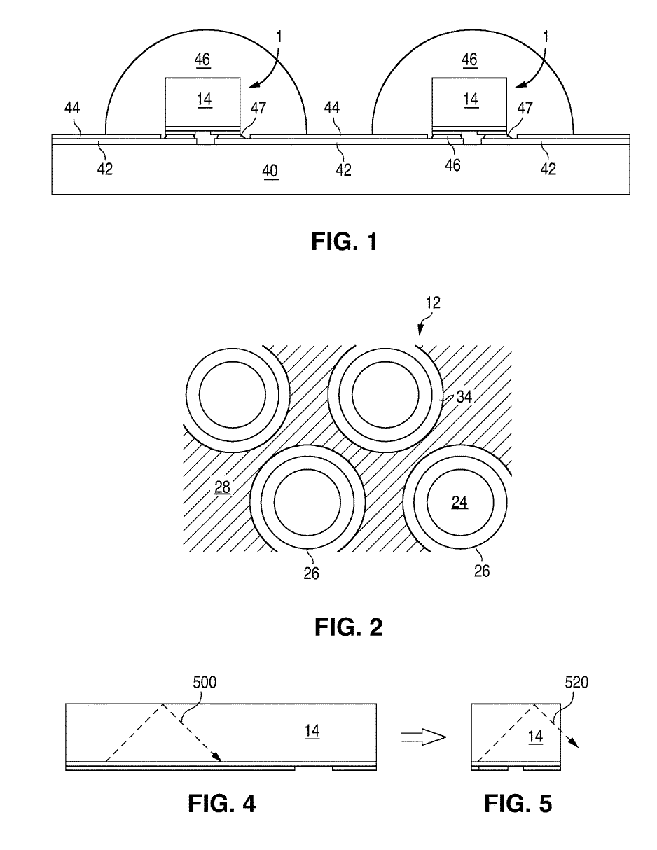

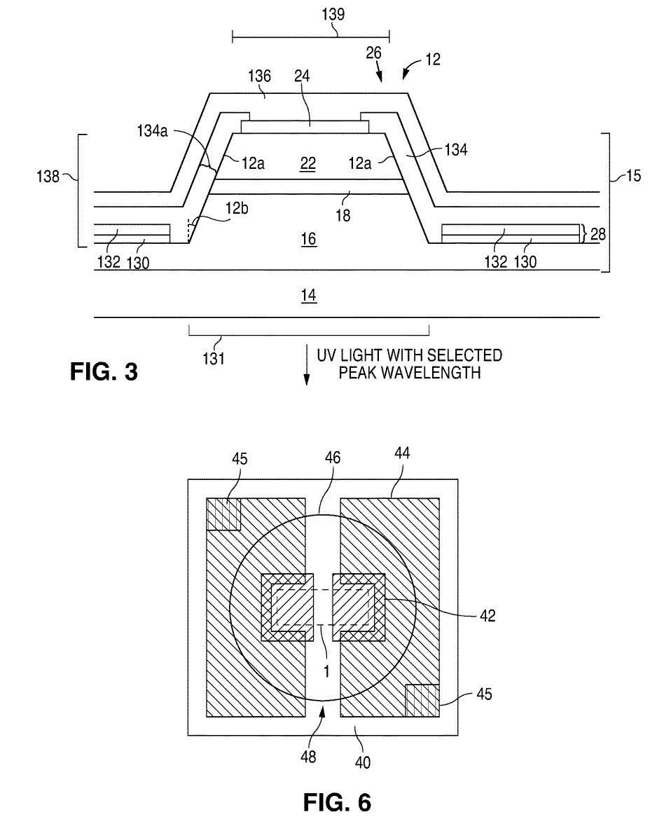

FIG. 1 illustrates a UVLED disposed on a mount, according to embodiments of the invention. In the structure of FIG. 1, two UVLEDs 1 are attached to a mount 40. One example of a suitable UVLED is described in detail below in the text accompanying FIGS. 2 and 3.

Mount 40 may be any suitable material that is highly thermally conductive (for example, with a thermal conductivity of at least 170 W/mK in some embodiments), highly electrically insulating, and mechanically rigid (for example, with a coefficient of thermal expansion that matches or is close to that of UVLED 1). Examples of suitable materials for mount 40 include but are not limited to ceramic, diamond, AN, beryllium oxide, silicon or electrically conductive material such as silicon, metal, alloy, Al, or Cu, provided the electrically conductive material is appropriately coated with an insulating layer such as silicon oxide, silicon nitride or aluminum oxide, or any other suitable material. In some embodiments, circuitry and/or other structures such as transient voltage suppression circuitry, driver circuitry, or any other suitable circuitry may be disposed within mount 40, or mounted on a surface of mount 40, such that the circuitry or other structures are electrically connected to UVLED 1, if necessary.

Conductive pads 42 are formed on the top surface of the mount. UVLED 1 is electrically and physically connected to mount 40 through pads 42. At least two electrically isolated pads 42 are provided per UVLED 1, one coupled to the n-type region of the UVLED 1 and one coupled to the p-type region of the UVLED 1. Pads 42 may be, for example, any material that is suitable for bonding UVLED 1 including, for example, gold, silver, tin-silver-copper (SAC), or gold-tin (AuSn). Pads 42 may be formed on the surface of mount 40 by any suitable technique including, for example, plating.

The contacts of UVLED 1 (described below) are connected to pads 42 by an interconnect 46, which may be any suitable material such as, for example, solder or gold. UVLED 1 may be connected to pads 42 by any suitable technique including, for example, gold-gold interconnection, soldering, or flux-assisted eutectic reflow techniques.

The area on the mount 40 surrounding UVLED 1 is coated with a reflective layer 44. Reflective layer 44 is a material that is highly reflective to the radiative power emitted by UVLED 1. Reflective layer 44 may be any suitable material including, for example, a metal, aluminum, multi-layer metal stacks, alloys, or reflective particles such as Polytetrafluoroethylene (PTFE, which may be known by the trade name Teflon®) or aluminum oxide disposed in a transparent material, such as UV-resistant silicone. Reflective layer 44 is at least 70% reflective of radiative power with wavelengths between 250 and 350 nm in some embodiments, and at least 85% reflective of radiative power with wavelengths between 250 and 350 nm in some embodiments.

A metal reflective layer 44 such as aluminum may be formed by, for example, plating, electron beam deposition, or evaporation. Reflective layer 44 may be a metal stack. For example, one or more layers that facilitate adhesion of the metal reflective layer 44 to the underlying surface (for example, a surface of mount 40 and/or a surface of pads 42) may be formed prior to metal reflective layer 44. Examples of such adhesion layers include nickel, titanium, or alloys thereof. One example of a suitable metal stack is 100 nm Ti disposed in direct contact with the underlying surface, followed by 500 nm Al. The metal stack may be formed by any suitable technique. In one embodiment, the metal stack can be formed by e-beam deposition, and the pattern can be formed by a photoresist lift-off process as is known in the art.

A reflective layer 44 that is reflective particles disposed in a transparent material may be formed by, for example, dispensing, molding, stencil printing, screen printing, or any other suitable technique. Reflective particles may be Al₂O₃, polytetrafluoroethylene (PTFE), or Al, disposed in silicone or any other suitable material that is low index, UV-resistant, and transparent to light between for example 250 nm and 350 nm. In some embodiments, the transparent material is electrically insulating. In some embodiments, the difference in refractive index between the particles and the transparent material causes scattering of light incident on the reflective layer 44. For example, commercially available UV-suitable silicone (such as, for example, Schott UV-200) may have a refractive index of no more than 1.42. Al₂O₃ particles may have a refractive index of 1.8. The difference between 1.42 and 1.8 may cause suitable scattering. The particles may be micron sized or nanometer sized.

Reflective layer 44 may improve extraction from the device illustrated in FIG. 1.

An optical element such as a lens 46 is disposed over the UVLED 1. Though a dome lens is illustrated in FIG. 1, any suitable optic, such as a Fresnel lens, other lens, or other optic, may be used. In some embodiments, lens 46 is a solid material. The lens 46 may be, for example, rotationally symmetric, oval, round, square, rectangular, triangular, or any other suitable shape. A dome lens may have a hemispherical, elliptical, or parabolic shape. Lens 46 is formed from a material that is transparent to UV radiation at wavelengths emitted by UVLED 1, and able to withstand the UV radiation without degrading. For example, in some embodiments, the optic may be formed from a material that transmits at least 85% of UV radiation at 280 nm, when a typical height of the optic is ˜2× the width of the UVLED 1. The transparency of the material may degrade no more than 1% after 1000 hrs of exposure to UV radiation at 280 nm. In some embodiments, lens 46 is formed from a material that is moldable, such as, for example, fused silica, glass, IHU UV transmissive glass available from Isuzu Glass, Inc., and UV-resistant silicone. In some embodiments, lens 46 is formed from a material that may be shaped by, for example, grinding and polishing, such as quartz or sapphire. An optic formed by molding may be less expensive; an optic formed by grinding and polishing may be of better optical quality.

In some embodiments, the height of lens 46 at the tallest point is kept small to maintain transparency. The height of the tallest point of lens 46 relative to the top surface of reflective layer 44 may be at least 50 μm in some embodiments, no more than 1 mm in some embodiments, no more than 750 μm in some embodiments, and no more than 500 μm in some embodiments. In some embodiments, rather than a lens designed to alter the beam of extracted light, optical element 46 may be a clear sheet of material, such as a quartz plate, that protects UVLED 1 without significantly altering the beam of extracted light.

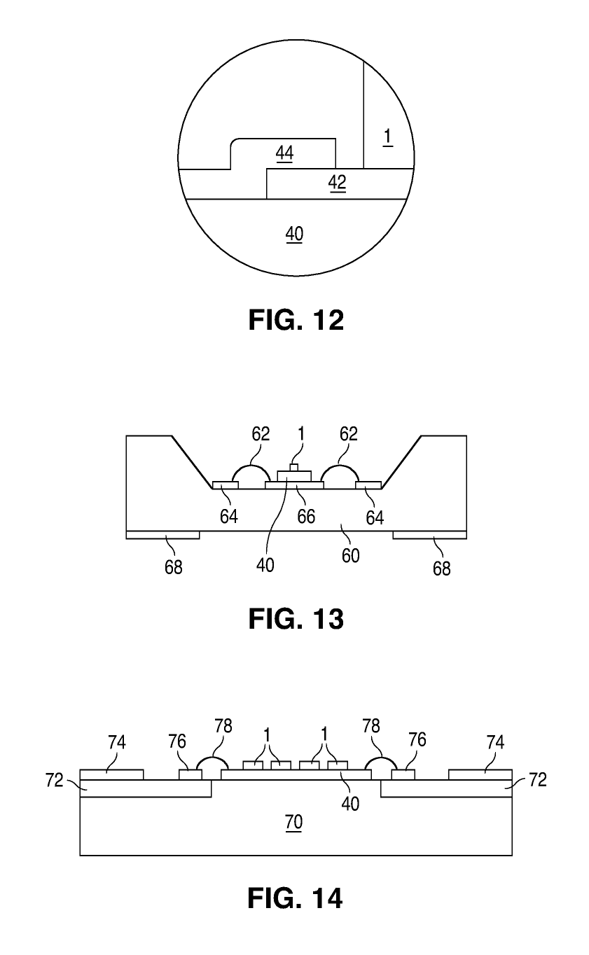

FIG. 6 is a top view of one of the devices illustrated in FIG. 1. Lens 46 extends beyond UVLED 1. The outline of UVLED 1 is a dashed line in FIG. 6. In the embodiment illustrated in FIG. 6, the pads 42 have substantially the same lateral extent as UVLED 1, such that the lateral extent of pads 42 is significantly less than that of reflective layer 44. Accordingly, as illustrated in FIG. 12, a portion of reflective layer 44 is disposed on pads 42, and a portion of reflective layer 44 is disposed directly on mount 40. In some embodiments, pads 42 may have a larger lateral extent, such that they are disposed under a larger portion of reflective layer 44, or under all of reflective layer 44. If reflective layer 44 is conductive, two reflective layers 44 may be separated by a gap 48, to avoid shorting the n- and p-contacts of UVLED 1. If reflective layer 44 is not conductive, the gap 48 may be omitted.

Bond pads 47 may be formed on the top surface of the mount, to facilitate electrical connection between UVLED 1 and another structure. Bond pads 47 must be electrically connected to pads 42. If reflective layer 44 is conductive (such as, for example, aluminum), bond pads may be formed on reflective layer 44.

Commercially available UVA, UVB, and UVC LEDs may be used in the various embodiments. FIGS. 2 and 3 illustrate a portion of one example of the assignee's own UVB and UVC LEDs, which may be used in embodiments of the invention. FIG. 2 is a top down view of a portion of a UVLED composed of an array of UVLED pixels 12. FIG. 3 is a bisected cross-section of a single UVLED pixel 12. Any suitable UVLED may be used and embodiments of the invention are not limited to the structures illustrated in FIGS. 2 and 3.

The UVLEDs are typically III-nitride, and commonly GaN, AlGaN, and InGaN. The array of UV emitting pixels 12 is formed on a single substrate 14, such as a transparent sapphire substrate. Other substrates are possible. Although the example shows the pixels 12 being round, they may have any shape, such as square. The light escapes through the transparent substrate, as shown in FIG. 3. The pixels 12 may each be flip-chips, where the anode and cathode electrodes face the mount.

Semiconductor layers are epitaxially grown over the substrate 14. (The device may include one or more semiconductor layers, such as conductive oxides such as indium tin oxide, that are not epitaxially grown, but are deposited or otherwise formed.) An AlN or other suitable buffer layer (not shown) is grown, followed by an n-type region 16. The n-type region 16 may include multiple layers of different compositions, dopant concentrations, and thicknesses. The n-type region 16 may include at least one AlₐGa₁₋ₐN film doped n-type with Si, Ge and/or other suitable n-type dopants. The n-type region 16 may have a thickness from about 100 nm to about 10 microns and is grown directly on the buffer layer(s). The doping level of Si in the n-type region 16 may range from 1×10¹⁶ cm⁻³ to 1×10²¹ cm⁻³. Depending on the intended emission wavelength, the AlN mole fraction “a” in the formula may vary from 0% for devices emitting at 360 nm to 100% for devices designed to emit at 200 nm.

An active region 18 is grown over the n-type region 16. The active region 18 may include either a single quantum well or multiple quantum wells (MQWs) separated by barrier layers. The quantum well and barrier layers contain AlₓGa₁₋ₓN/Al_{y}Ga_{1-y}N, wherein 0<x<y<1, x represents the AlN mole fraction of a quantum well layer, and y represents the AlN mole fraction of a barrier layer. The peak wavelength emitted by a UV LED is generally dependent upon the relative content of Al in the AlGaN quantum well active layer.

A p-type region 22 is grown over the active region 18. Like the n-type region 16, the p-type region 22 may include multiple layers of different compositions, dopant concentrations, and thicknesses. The p-type region 22 includes one or more p-type doped (e.g. Mg-doped) AlGaN layers. The AlN mole fraction can range from 0 to 100%, and the thickness of this layer or multilayer can range from about 2 nm to about 100 nm (single layer) or to about 500 nm (multilayer). A multilayer used in this region can improve lateral conductivity. The Mg doping level may vary from 1×10¹⁶ cm⁻³ to 1×10²¹ cm⁻³. A Mg-doped GaN contact layer may be grown last in the p-type region 22.

All or some of the semiconductor layers described above may be grown under excess Ga conditions, as described in more detail in US 2014/0103289, which is incorporated herein by reference.

The semiconductor structure 15 is etched to form trenches between the pixels 12 that reveal a surface of the n-type region 16. The sidewalls 12a of the pixels 12 may be vertical or sloped with an acute angle 12b relative to a normal to a major surface of the growth substrate. The height 138 of each pixel 12 may be between 0.1-5 microns. The widths 131 and 139 at the bottom and top of each pixel 12 may be at least 5 microns. Other dimensions may also be used.

Before or after etching the semiconductor structure 15 to form the trenches, a metal p-contact 24 is deposited and patterned on the top of each pixel 12. The p-contact 24 may include one or more metal layers that form an ohmic contact, and one or more metal layers that form a reflector. One example of a suitable p-contact 24 includes a Ni/Ag/Ti multi-layer contact.

An n-contact 28 is deposited and patterned, such that n-contact 28 is disposed on the substantially flat surface of the n-type region 16 between the pixels 12. The n-contact 28 may include a single or multiple metal layers. The n-contact 28 may include, for example, an ohmic n-contact 130 in direct contact with the n-type region 16, and an n-trace metal layer 132 formed over the ohmic n-contact 130. The ohmic n-contact 130 may be, for example, a V/Al/Ti multi-layer contact. The n-trace metal 132 may be, for example, a Ti/Au/Ti multi-layer contact.

The n-contact 28 and the p-contact 24 are electrically isolated by a dielectric layer 134. Dielectric layer 134 may be any suitable material such as, for example, one or more oxides of silicon, and/or one or more nitrides of silicon, formed by any suitable method. Dielectric layer 134 covers n-contact 28. Openings formed in dielectric layer 134 expose p-contact 24.

A p-trace metal 136 is formed over the top surface of the device, and substantially conformally covers the entire top surface. The p-trace metal 136 electrically connects to the p-contact 24 in the openings formed in dielectric layer 134. The p-trace metal 136 is electrically isolated from n-contact 28 by dielectric layer 134.

Robust metal pads electrically connected to the p-trace metal 136 and n-contact 28 are provided outside of the drawing for connection to the mount. Multiple pixels 12 are included in a single UVLED. The pixels are electrically connected by large area p-trace metal 136 and the large area n-trace metal 132. The number of pixels may be selected based on the application and/or desired radiation output. A single UVLED, which includes multiple pixels, is illustrated in the following figures as UVLED 1.

In some embodiments, substrate 14 is sapphire. Substrate 14 may be, for example, on the order of a hundred of microns thick. Substrate 14 may remain part of the device in some embodiments, and may be removed from the semiconductor structure in some embodiments.

The UVLED may be square, rectangular, or any other suitable shape when viewed from the top surface of substrate 14, when the device is flipped relative to the orientation illustrated in FIG. 3.

In some embodiments, UVLED 1 is kept small to improve light extraction. FIGS. 4 and 5 illustrate how the size of UVLED 1 impacts the extraction of radiative power from UVLED 1. FIG. 4 illustrates a large device and FIG. 5 illustrates a small device. In both UVLEDs of FIGS. 4 and 5, the growth substrate 14 is often sapphire. Sapphire has a high index of refraction compared to the air surrounding the UVLED, thus some radiative power incident on the interface between the substrate 14 and the surrounding air is reflected by total internal reflection, as illustrated by rays 50 in FIGS. 4 and 52 in FIG. 5. If the reflected radiative power is incident on the semiconductor structure, as illustrated in the large device of FIG. 4, it is often absorbed. In a small device, illustrated by FIG. 5, the reflected light may be extracted from a sidewall of substrate 14.

The length of the UVLED of FIG. 4 may be, for example, at least 1 mm. The length of a side of the small UVLED of FIG. 5 may be at least 50 μm in some embodiments, no more than 500 μm in some embodiments, no more than 300 μm in some embodiments, and no more than 200 μm in some embodiments. Small devices may be rectangular, square, or any other suitable shape. Modeling illustrates that in a square device, reducing the length of a side from 1 mm to 500 μm may increase extraction of radiative power by 31%, and reducing the length of a side from 1 mm to 200 μm may increase extraction of radiative power by 75%. The thickness of the sapphire substrate may be 200 μm in some embodiments, more than 200 μm in some embodiments, and less than 1 mm in some embodiments.

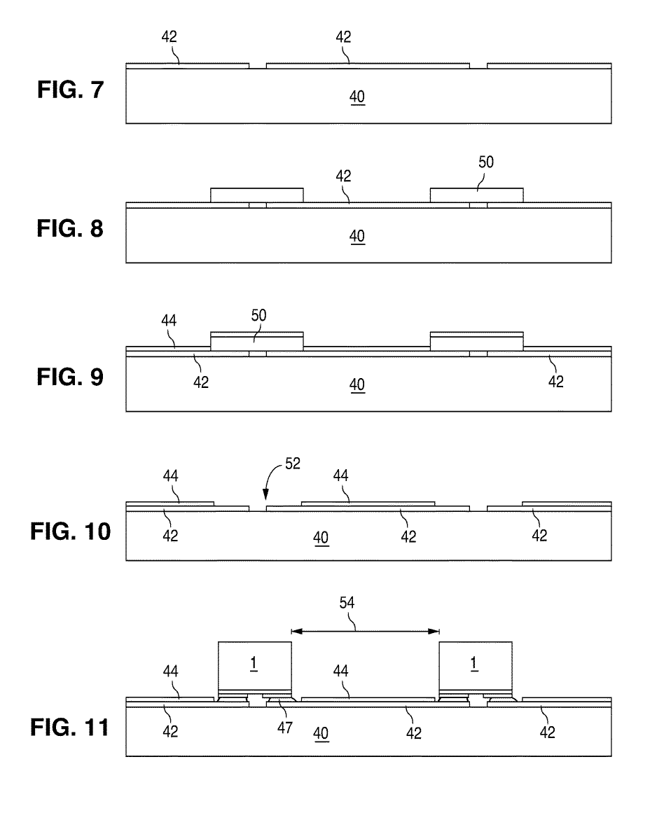

FIGS. 7, 8, 9, 10, and 11 illustrate forming the device illustrated in FIG. 1.

In FIG. 7, the metal that forms pads 42 is deposited on mount 40, and patterned, for example by photolithography.

In FIG. 8, a mask material is deposited over mount 40 and pads 52 and patterned such that mask segments 50 are disposed in the areas where reflective layer 44 is to be removed (corresponding to where UVLEDs 1 will be positioned).

In FIG. 9, reflective layer 44 is formed over pads 42 and mask segments 50. Techniques for forming reflective layer 44 are described above.

In FIG. 10, mask segments 50, and the reflective layer 44 overlying mask segments 50, are removed, leaving reflective layer 44 with openings 52 where UVLEDs 1 are to be placed.

In FIG. 11, UVLEDs 1 are positioned in openings 52 and attached to pads 42 on mount 40 by interconnects 46. Interconnects 46 may be disposed on UVLED 1, on pads 42, or both prior to mounting UVLED 1 on mount 40.

Lenses 46 may be disposed over individual UVLEDs 1 as illustrated in FIG. 1, for example by molding or by attaching a pre-formed lens to the top surface of UVLED 1, to a surface of the mount or layers formed on the mount, or both.

In some embodiments, the panel of packaged devices is diced into individual devices. In that case, the spacing 54 between neighboring devices may be the clearance needed to singulate mount 40 without causing damage, or the clearance needed plus the width of the mount desired for particular optical characteristics.

In some embodiments, multiple, packaged UVLEDs form a final product. In that case, the spacing 54 between neighboring UVLEDs may be selected to be large enough that neighboring UVLEDs absorb little or no light from each other. In some embodiments, the spacing 54 is at least three times the height of UVLED 1 relative to the top surface of mount 40 or to the top surface of the layers 42, 44 formed on mount 40. In some embodiments, the spacing 54 is at least 100 μm in some embodiments, no more than 1 mm in some embodiments, no more than 800 μm in some embodiments, and no more than 600 μm in some embodiments.

FIGS. 13, 14 and 15 illustrate three structures on which the packaged UVLEDs described above may be mounted. In FIG. 13, structure 60 is shaped into a reflector cup. A UVLED 1 disposed on a mount 40, as described above in embodiments of the invention, is disposed at the bottom of the reflector cup and attached to structure 60 via bonding pad 66. Wire bonds 62 electrically connect mount 40 to pads 64 adjacent mount 40. Pads 64 may connect to pads 68 disposed on the bottom of structure 60.

In FIG. 14, multiple UVLEDs 1 are disposed on a mount 40. The mount 40 is disposed on a conductive slug 70, such as a copper slug. The mount 40 is wire bonded 78 to pads 76, which are electrically isolated from the conductive slug 70 by insulating layers 72. Pads 74 may electrically connect the structure to another structure.

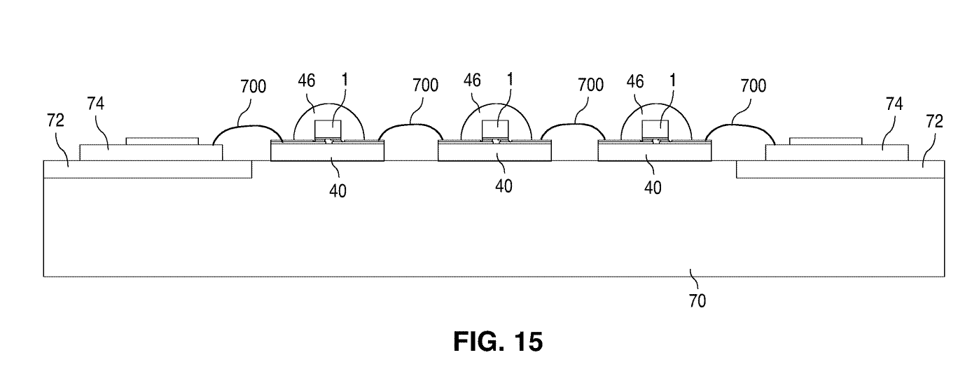

In FIG. 15, one or multiple UVLEDs 1 are disposed on a mount 40. Multiple mounts 40 are disposed on a conductive slug 70, such as a copper slug, to form an array. The mounts 40 are wire bonded 700 to each other, and wire bonded 700 to pads 74, which are electrically isolated from the conductive slug 70 by insulating layers 72. Pads 74 may electrically connect the structure to another structure.

Having described the invention in detail, those skilled in the art will appreciate that, given the present disclosure, modifications may be made to the invention without departing from the spirit of the inventive concept described herein. In particular, different features and components of the different devices described herein may be used in any of the other devices, or features and components may be omitted from any of the devices. A characteristic of a structure described in the context of one embodiment, may be applicable to any embodiment. Therefore, it is not intended that the scope of the invention be limited to the specific embodiments illustrated and described.

1. A device comprising:
a light emitting diode (UVLED) comprising a semiconductor structure comprising an active layer disposed between an n-type region and a p-type region, wherein the active layer emits UV radiation;
a mount comprising electrical connection pads formed on a top surface of the mount, wherein the UVLED is disposed on the mount and attached to the electrical connection pads; and
a reflective layer disposed over portions of the electrical connection pads in direct contact with the electrical connection pads, surrounding the UVLED, wherein a first portion of the reflective layer is disposed over the electrical connection pads in direct contact with the electrical connection pads, and a second portion of the reflective layer is in direct contact with a top surface of the mount.

2. The device of claim 1 further comprising a lens disposed over the UVLED.

3. (canceled)

4. The device of claim 1 wherein the reflective layer comprises aluminum and the electrical connection pads comprise gold.

5. The device of claim 1 wherein the reflective layer comprises particles disposed in a transparent material and the electrical connection pads comprise gold.

6. The device of claim 5 wherein the particles are one of polytetrafluoroethylene (PTFE) and Al₂O₃.

7. A method comprising:
disposing first and second electrical pads on a mount;
disposing a reflective layer overlying and in direct contact with first portions of the first and second electrical pads;
patterning the reflective layer to form an opening that exposes second portions of the first and second electrical pads; and
electrically and physically connecting to the first and second electrical pads a light emitting diode (UVLED) comprising a semiconductor structure comprising an active layer disposed between an n-type region and a p-type region, wherein the active layer emits UV radiation.

8. The method of claim 7 wherein disposing a reflective layer overlying first portions of the first and second electrical pads comprises electron-beam deposition of aluminum.

9. The method of claim 7 wherein disposing a reflective layer overlying first portions of the first and second electrical pads comprises one of screen printing, stencil printing, dispensing, and molding a mixture of particles and a transparent material.

10. The method of claim 7 further comprising molding a lens over the UVLED such that the lens is disposed over the reflective layer.

11. The device of claim 2 wherein the reflective layer is disposed beneath the lens.

12. The device of claim 2 wherein the lens is disposed along the sidewall of the UVLED.

13. The device of claim 1 wherein a first portion of the reflective layer is disposed over the electrical connection pads in direct contact with the electrical connection pads, and a second portion of the reflective layer is in direct contact with a top surface of the mount.

14. The device of claim 1 wherein a length of a side of the UVLED is no more than 500 μm.

15. A device comprising:
a light emitting diode (UVLED) comprising a semiconductor structure comprising an active layer disposed between an n-type region and a p-type region, wherein the active layer emits UV radiation;
a mount comprising electrical connection pads formed on a top surface of the mount, wherein the UVLED is disposed on the mount and attached to the electrical connection pads; and
a reflective layer disposed over portions of the electrical connection pads in direct contact with the electrical connection pads, surrounding the UVLED, wherein the reflective layer comprises a Ti layer in direct contact with the electrical connection pad and an Al layer disposed on the Ti layer.

16. The device of claim 1 wherein the reflective layer is electrically conductive.

17-20. (canceled)

21. The device of claim 15 further comprising a lens disposed over the UVLED.

22. The device of claim 21 wherein the reflective layer is disposed beneath the lens.

23. The device of claim 15 wherein the electrical connection pads comprise gold.

24. The device of claim 15 wherein a first portion of the reflective layer is disposed over the electrical connection pads in direct contact with the electrical connection pads, and a second portion of the reflective layer is in direct contact with a top surface of the mount.
